(19) United States
(12) Patent Application Publication
(10) Pub. No.: US 2016/0284425 A1
(43) Pub. Date: Sep. 29, 2016

(54) Ternary Content Addressable Memory Scan-Engine

(71) Applicant: Broadcom Corporation, Irvine, CA (US)

(72) Inventors: Abhay Kumar Kulkarni, Milpitas, CA (US); Kunta Tsai, San Jose, CA (US)

(21) Appl. No.: 14/705,333

(22) Filed: May 6, 2015

Related U.S. Application Data
(60) Provisional application No. 62/136,920, filed on Mar. 23, 2015.

(51) Int. Cl. G11C 29/42; H03M 13/27; G11C 29/36

(52) U.S. Cl. CPC G11C 29/42; G11C 29/36; H03M 13/2792

(57) ABSTRACT

A packet processing pipeline very efficiently checks for parity errors in memories located along the packet pipeline. The parity check is highly parallelized. For instance, individual unit layouts that are the constituent memory instances of a particular memory execute the parity check in parallel. As another example, each memory along the packet pipeline executes the parity check in parallel with the other memories at other pipeline stages. The parity computation and parity check operations may be implemented in hardware for extremely fast execution.

### PRIORITY CLAIM

This application claims priority to provisional application Ser. No. 62/136,920, filed Mar. 23, 2015, which is entirely incorporated by reference.

### TECHNICAL FIELD

This disclosure relates to testing memory systems. This disclosure also relates to error detection for memories used in network devices, such as switches.

### BACKGROUND

High speed data networks form part of the backbone of what has become indispensable worldwide data connectivity. Within the data networks, network devices such as switching devices direct data packets from source ports to destination ports, helping to eventually guide the data packets from a source to a destination. Improvements in memory system design and implementation, including improvements in error detection, will further enhance the performance of data networks.

### BRIEF DESCRIPTION OF THE DRAWINGS

FIG. 1 shows an example network in which switches route packets from sources to destinations.

FIG. 2 illustrates an example of a network device that includes a packet pipeline.

FIG. 3 shows several examples of memory database architectures that may be used for the memory database examples in the packet pipeline.

FIG. 4 shows a very large scale integration (VLSI) macro that provides individual instances of memory arrays that may be used as building blocks to form larger memories used as memory databases in the packet pipeline.

FIG. 5 shows a pipeline cycle diagram illustrating parallel processing of parity checks among the memory databases.

FIG. 6 shows logic for parity checking memory databases in parallel along a packet pipeline.

FIG. 7 shows logic for parity error handling.

### DETAILED DESCRIPTION

As an introduction, the architecture and techniques described below allow a pipeline, such as a packet processing pipeline, to very efficiently check for parity errors in memories located along the pipeline. The memories may be implemented with one or more individual units of a very large scale integration (VLSI) layout or macro. These units provide the constituent memory instances that are interconnected to form each memory database along the packet pipeline.

The parity checks are highly parallelized. As one example, each memory along the packet pipeline executes the parity check in parallel with the other memories at other pipeline stages. As another example, the individual memory instances within a given memory also execute the parity check in parallel. The parity check and parity computation operations may be implemented in hardware for extremely fast execution.

The memories may be ternary content addressable memories (TCAMs), for instance. The TCAMs may implement any desired functionality for the packet processing pipeline. As examples, any of the TCAM memories, at any stage of the pipeline, may implement tunneling tables, access control lists (ACLs), forwarding databases, datamining databases for flexible parsers, L3 forwarding tables, e.g., longest prefix match tables, or other any databases or memory content.

The architecture for parity checking the memories in the packet processing pipeline has several technical benefits. As one example, the time consumed to parity check all of the memories is greatly reduced compared to, for instance, a software based linear background scan approach. Depending on the memory implementation and the number of memories, the reduction may be from several seconds to 100 microseconds or less. One beneficial result is a dramatic increase in reliability, reflected in measured increases in failure metrics computed for the chips that include the architecture, e.g., increase in mean time between failure (MTBF). Furthermore, there is extremely low software load and CPU load, which means that customers see less performance impact on their applications. In addition, the architecture is very scalable, and efficiently accommodates additional memories at additional pipeline stages, and well as deeper instances of the memories at each pipeline stage.

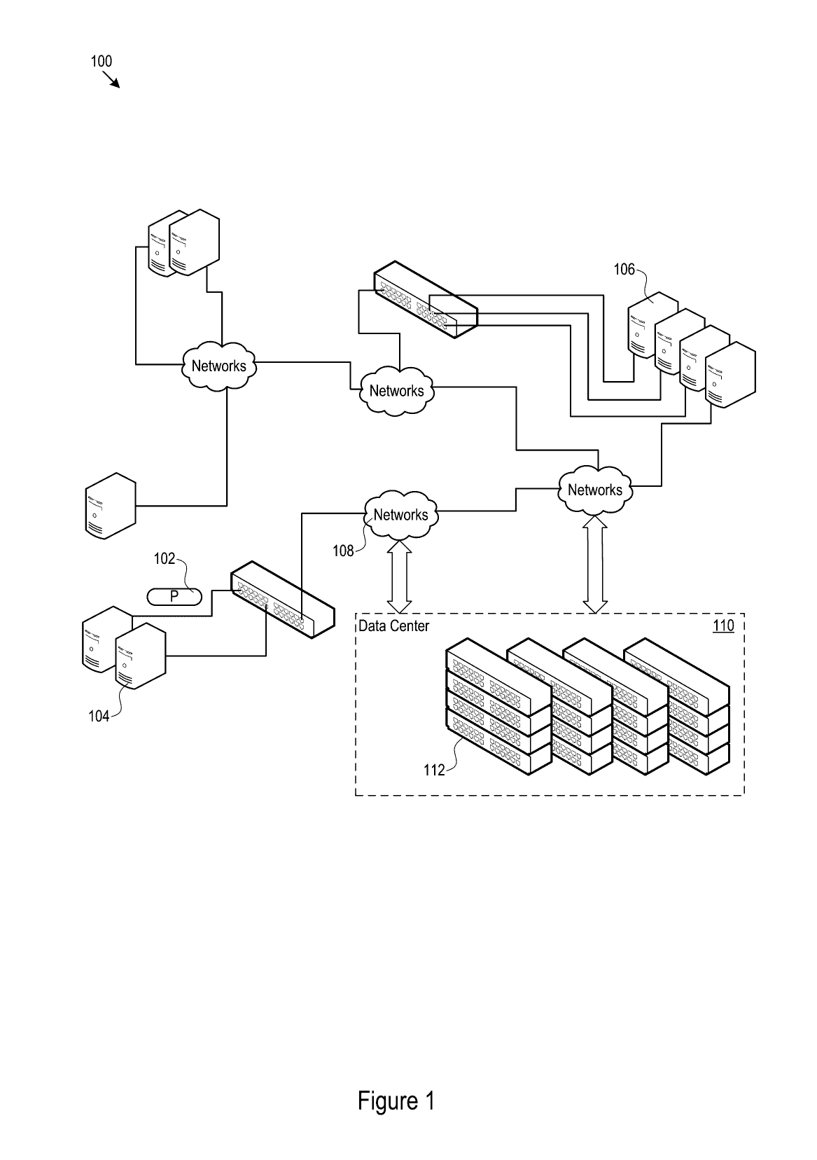

FIG. 1 shows an example network 100 in which networking devices route packets (e.g., the packet 102) from sources (e.g., the source 104) to destinations (e.g., the destination 106) across networks (e.g., the network 108). The networking devices may take many different forms, including switches, routers, hubs and other networking devices. In the datacenter 110, for instance, there may be an extremely dense array of switches 112.

The switches in the datacenter 110 and elsewhere play a crucial role in supporting high volume data communication to different websites. In many cases, unexpected interruptions in switch operation can cause extremely severe consequences. For instance, soft errors due to alpha particle emission or energetic neutrons and protons from cosmic radiation may cause unexpected network reconfigurations or other issues, leading to significant loss in revenue. The architecture and techniques described below improve the reliability of any device with a processing pipeline, and in particular improve the reliability of packet switches.

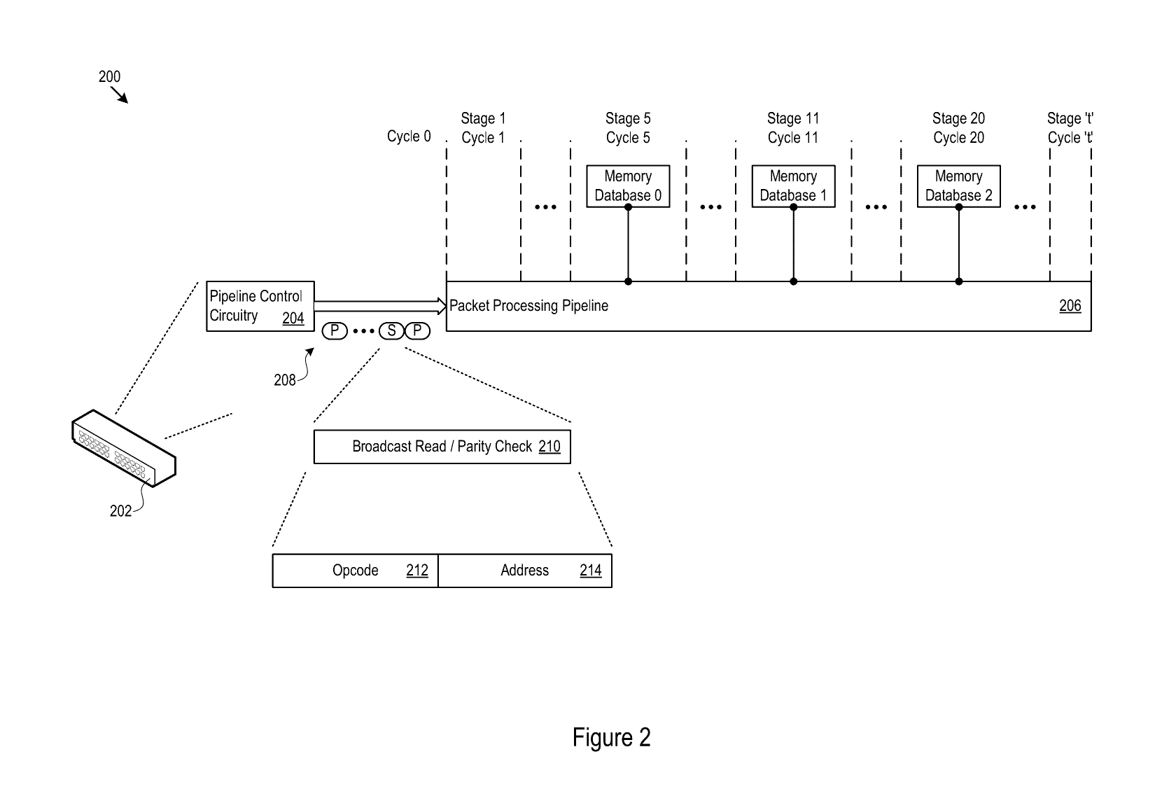

FIG. 2 illustrates an example of a network device 200 that includes a packet pipeline. In this example, the network device is a switch 202. The switch 202 includes pipeline control circuitry 204 and a packet pipeline 206. The pipeline control circuitry 204 may, among other responsibilities, coordinate submission of packets 208 to the packet pipeline 206, e.g., according to any pre-determined schedule.

The packets 208 include general purpose data packets ‘P’ as well as special purpose packets ‘S’. The general purpose packets ‘P’ represent, e.g., packets that the switch is helping to route from an ultimate source device (e.g., a home PC) to an ultimate destination device (e.g., an e-commerce server). The special purpose packets ‘S’ represent, e.g., packet pipeline configuration and instruction packets. One example of an instruction packet is a broadcast read instruction 210 for performing parity checks.

One or more memories at one or more stages of the packet pipeline 206 may respond to a broadcast read instruction by performing a parity check operation. The broadcast read instruction 210 may specify an opcode 212 with a bit pattern that identifies the broadcast read instruction, and the address 214 at which to perform the parity check. For instance, each TCAM memory database at each stage of the packet pipeline may respond in parallel to the broadcast read instruction by checking parity at a specified address in that particular TCAM memory database.

The packet pipeline 206 includes multiple stages, shown in FIG. 2 as stage 1 to stage ‘t’. There may be any number of stages in any given packet pipeline 206, e.g., between 2 and 100 stages. Each clock cycle propagates a packet along the packet pipeline to the next stage. Each stage may be responsible for handling all or part of any allocated processing task. In support of those tasks, any stage may include a memory database to facilitate, as examples, ACL lookup, L3 lookup, packet forwarding, or any other task. In the example of FIG. 2, memory database 0 is present at stage 5, memory database 1 is present at stage 11, and memory database 2 is present at stage 20.

As will be described in more detail below, the pipeline control circuitry 204 is configured to issue broadcast read instructions into the packet processing pipeline 206 at selected clock cycles. Each memory database may be configured to recognize the broadcast read instruction and perform a parity test of that memory database responsive to the broadcast read instruction. In that respect, the broadcast read instruction acts as a type of scan instruction to facilitate scanning for parity errors in the memory databases. It is not required that every memory database respond to broadcast read instructions. Instead, in some implementations, only selected memory databases at any given pipeline stage may respond.

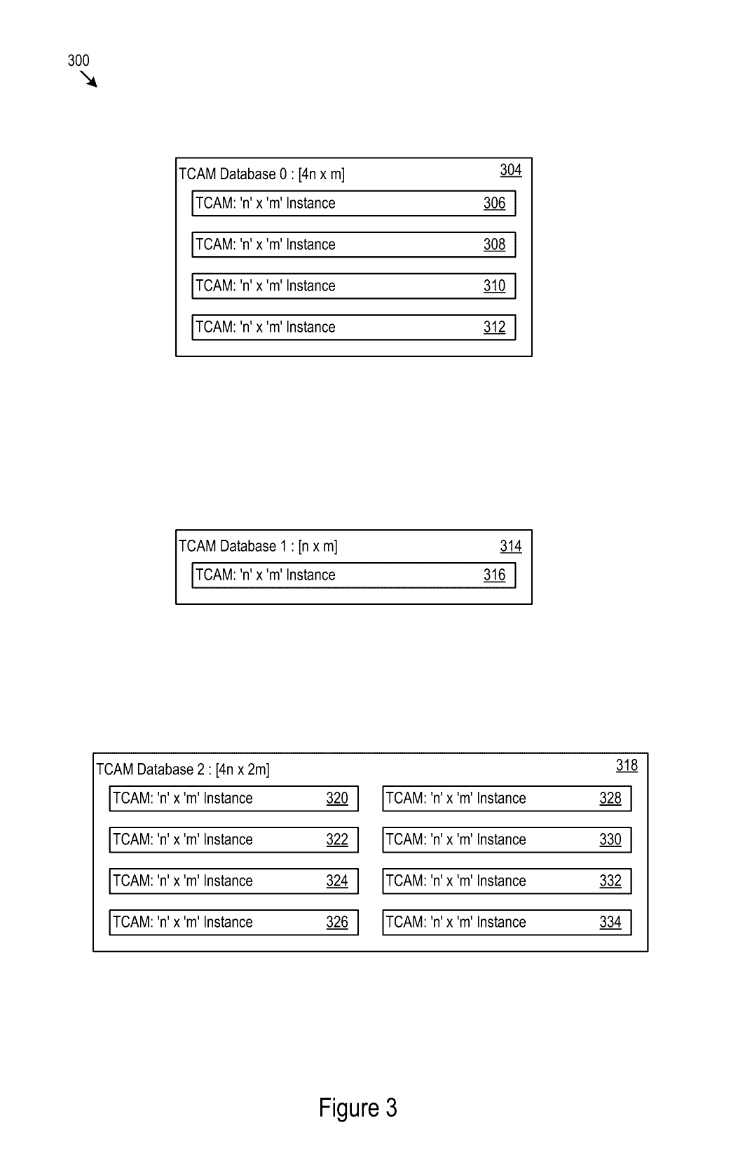

FIG. 3 shows several examples of TCAM memory database architectures 300 that may be used for the memory database examples in the packet pipeline 206. Memory database 0 is a 4n×m TCAM database 302. The architecture of the TCAM database 302 includes four individual instances of a pre-defined n×m TCAM macro block: the instance 306, the instance 308, the instance 310, and the instance 312. Memory database 1 is a n×m TCAM database 314. The architecture of the TCAM database 314 includes one instance of the pre-defined n×m macro block: the instance 316. Memory database 2 is a 4n×2m TCAM database 318. The architecture of the TCAM database 318 includes eight individual instances of the pre-defined n×m TCAM macro block, arranged four deep and two wide: the instances 320, 322, 324, 326, 328, 330, 332, and 334.

The overall width and depth of a memory database may vary widely, as just one example range, from 16×16 to 4096×386. The width and depth of any macro block instance providing a unit layout for the memory database may also vary widely, as just one example range, from 16×16 to 1024×192.

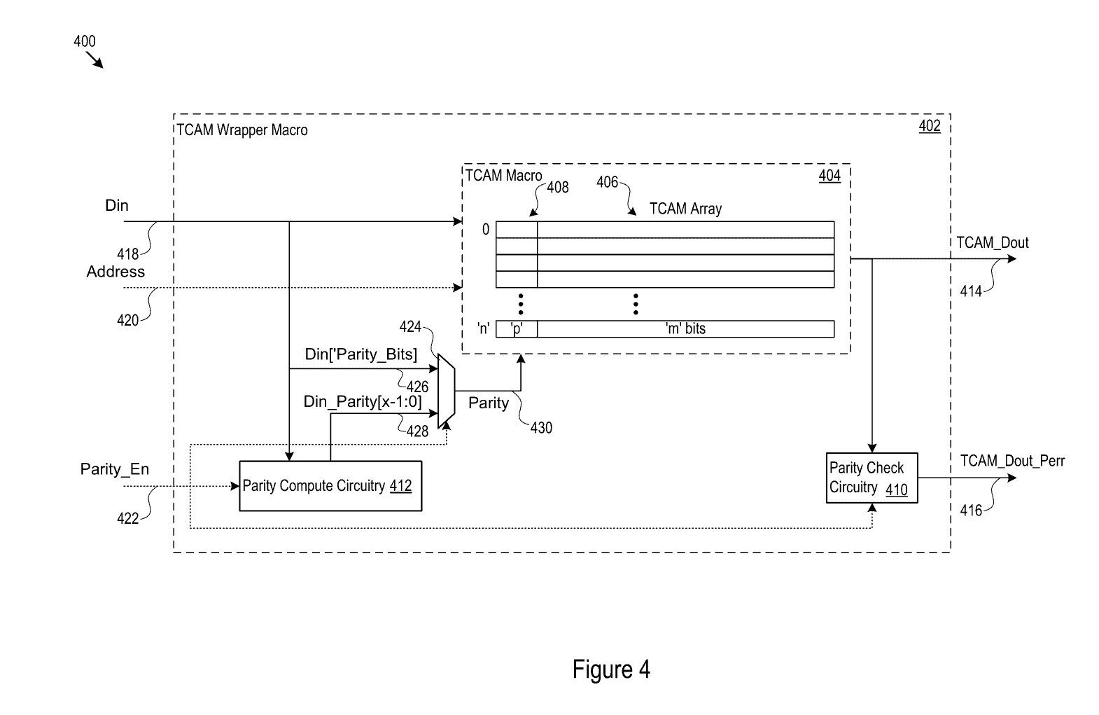

FIG. 4 shows an example of a very large scale integration (VLSI) macro 400. The macro 400 provides individual instances of memory arrays that may be used as building blocks to form larger memories used as memory databases in the packet pipeline 206. The example of FIG. 4 shows a TCAM wrapper macro 402 around a TCAM array macro 404. The TCAM array macro 404 defines a general purpose bit array 406, and a parity bit array 408.

The parity bit array 408 provides parity bits for the general purpose bit array 406. The general purpose bit array 406 is organized into data lines, e.g., data lines 0 through ‘n’. The number of bits in each data line may vary widely. The parity bit array 408 provides one or more parity bits, ‘p’, for each data line in the general purpose bit array 406. The parity bits for a given data line may encode even or odd parity, as examples, for the general purpose data bits, ‘m’, in that given data line.

In some implementations, there may be multiple parity bits for each data line, e.g., 2, 3, or 4 parity bits. The multiple parity bits may implement an interleaved parity bit array. Table 1, below, shows an example of four-bit interleaved parity for the data lines in the general purpose bit array 406.

TABLE 1

| | Parity bit computed over |
|---|---|
| Parity Bit | these general purpose bits in each line: |
| 0 | 0, 4, 8, 12, 16, 20, . . . |
| 1 | 1, 5, 9, 13, 17, 21, . . . |
| 2 | 2, 6, 10, 14, 18, 22, . . . |
| 3 | 3, 7, 11, 15, 19, 23, . . . |

The TCAM wrapper macro 402 also includes parity check circuitry 410 and parity compute circuitry 412. When a data line is read out of the memory array, the general purpose data and parity bits are present on the TCAM_Dout output 414. The parity check circuitry 410 receives the data, performs a parity check, and determines whether there is an error in any parity bit for the line. If there is a parity error, then the parity check circuitry 410 asserts the parity error output TCAM_Dout_Perr 416.

When data is stored in the memory array, the data is presented on the Din input 418 and the address is presented on the Address input 420. The parity enable input 422, Parity_En, determines whether the parity compute circuitry 412 will calculate parity bits. The parity enable input 422 also determines the output of the multiplexer 424, e.g., to cause the multiplexer 424 to output the parity bits 428 determined by the parity compute circuitry 412, or to output any other pre-determined data bits 426 from the input data. The multiplexer output 430 (which may or may not be parity bits, depending on Parity_En) are stored in the parity bit array 408 at the address specified by the address input 420.

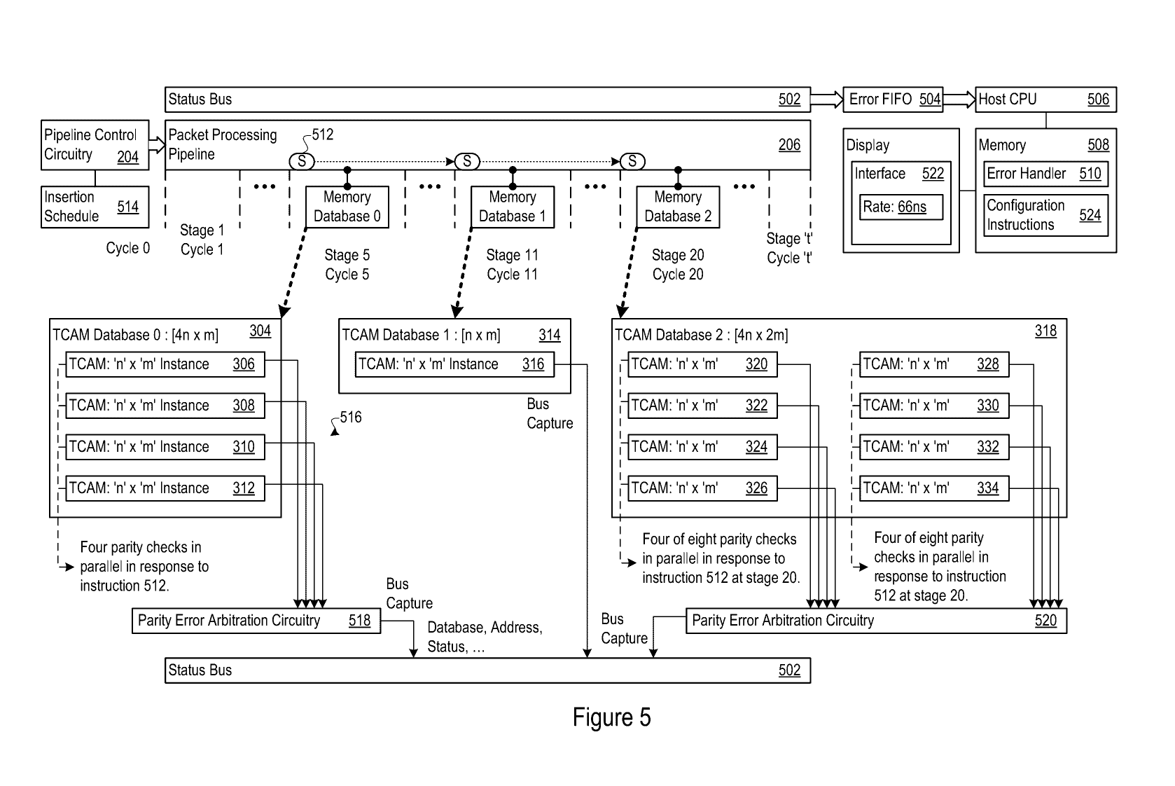

FIG. 5 shows a pipeline cycle diagram 500 illustrating parallel processing of parity checks. In the example of FIG. 5, the parity checks occur in parallel and in hardware among the memory databases 304, 314, 318 which implement memory database 0, memory database 1, and memory database 2, respectively. In the implementation shown in FIG. 5, the packet pipeline 206 includes a status bus 502 that flows along the packet pipeline 206. Among other functions, the status bus 502 may capture parity error information, propagate the parity error information along the pipeline, and store the parity error information in the error First-In-First-Out (FIFO) memory 504. The parity error information may vary widely, and as one example, may include an identifier (e.g. address) of the memory database in which the parity error occurred, the address within the memory database of the parity error, and additional status information, such as the number of parity errors, and (when there are multiple parity bits per data line) which parity bits indicate parity errors.

A host CPU 506 (or any other processing circuitry) may check the status of the error FIFO 504 at pre-determined times. When an error entry is present in the error FIFO 504, the host CPU may read the error entry for processing. As one example, the host CPU 506 may execute, from the memory 508, the error handler 510. The error handler 510 may report the error locally or remotely to an error reporting interface, take corrective actions, or take any other predetermined remediation actions.

In the example of FIG. 5, the pipeline control circuitry 204 has issued the broadcast read instruction 512. The broadcast read instruction 512 propagates down the packet pipeline 206. The pipeline control circuitry 204 determines selected clock cycles at which to issue the broadcast read instructions, e.g., interleaving the broadcast read instructions with general purpose packets. The selected clock cycles may correspond, for instance, to pre-scheduled overhead pipeline access time periods. These periods may be determined from an insertion schedule 514. The insertion schedule 514 may be pre-configured to provide an amount of guaranteed bandwidth into the packet pipeline 206 for, e.g., control, configuration, metering, or other access to the packet pipeline 206.

In other implementations, the pipeline control circuitry 204 issues broadcast read instructions at a pre-determined rate, e.g., every 66 ns. The predetermined rate may be a configurable rate. In one implementation, the rate is configured with the host CPU through a configuration interface 522 implemented, e.g., by the host CPU 506 executing configuration instructions 524. As another example, the pipeline control circuitry 204 may issue broadcast read instructions at a rate determined to accomplish a scan of selected (e.g., all) data lines in the memory databases in a specified time. For instance, if the deepest memory database is 2048 data lines, and the parity check will complete in 100 μs, then the pipeline control circuitry 204 may issue broadcast read instructions, on average, every 100 μs/2048=about 48 ns.

In that respect, the pipeline control circuitry 204 may issue a set of individual broadcast read instructions into the packet pipeline 206. The pipeline control circuitry 204 may specify sequentially incrementing addresses [0, 1, 2, . . . n−1] in sequential individual broadcast read instructions. For example, the addresses may be 0, 1, 2, . . . 2047 when the largest memory database is 2048 data lines deep. Note, however, that the pipeline control circuitry 204 may specify addresses that follow any desired test pattern or address sequence. As will be described in more detail below, the individual broadcast read instructions will test parity in parallel across the TCAM instances within a memory database, and in parallel at the different stages of the packet pipeline 206 where the memory databases are located.

The circuitry at each pipeline stage may recognize and respond to the broadcast read instructions. In particular, the memory databases may recognize the broadcast read instruction 512 and perform a parity test responsive to the broadcast read instruction 512. In doing so, each memory database may receive the broadcast read instruction opcode 212 and the specified address 214, recognize the instruction opcode 212 as a broadcast read instruction, and perform the parity check in each TCAM constituent module at the specified address 214.

For the example of FIG. 5, when memory database 0 receives the broadcast read instruction at pipeline stage 5, each of the four TCAM instances 306, 308, 310, and 312 executes the parity check in parallel for the data line specified as an address in the broadcast read instruction. As explained above with regard to FIG. 4, each TCAM instance includes parity check circuitry 410 and a parity error output 516, TCAM_Dout_Perr. In some implementations, the status bus 502 may capture and propagate one detected parity error down the status bus 502 at a time, and others may also follow sequentially as they are discovered. The error FIFO 504 stores the parity error information for each parity error captured on the status bus 502.

Parity error arbitration circuitry 518 determines a priority among multiple parity error outputs. As one example, the parity error arbitration circuitry 518 may implement a priority hierarchy among the specific TCAM instances within the memory database 0, for the purposes of reporting a parity error. The hierarchy may specify, for instance, priority according to increasing addresses, decreasing addresses, or any other selection order. When there are multiple parity errors, the TCAM instance with the highest priority captures the status bus 502, and places parity error information on the status bus 502.

The memory database 314 includes a single TCAM instance, and need not be connected to parity arbitration circuitry. The memory database 318 is implemented as eight units of TCAM instances, and may be connected to parity arbitration circuitry 520 to prioritize error reporting among the eight possible parity error outputs from the memory database 318. In other implementations, the parity error arbitration circuitry may be omitted, and the status bus 502 may capture each of the multiple parity errors detected.

The memory database 314 receives and executes the broadcast read instruction at cycle 5, and the memory database 318 receives and executes the broadcast read instruction at cycle 20. Note that all of the memory databases can execute a complete scan for parity errors with ‘n’ broadcast read instructions, because that is the maximum depth of a TCAM instance, and each TCAM instance executes parity checks in parallel with the other TCAM instances in a given memory database.

The memory databases 304, 314 and 318 execute parity checks in parallel with other broadcast read instructions being processing at other stages of the pipeline. This provides a second level of parallel execution of the parity checks. Again, there may be any number of memory databases at any stage in the packet pipeline 206, and FIG. 5 shows just one example for the purposes of explanation.

The architecture and techniques may be used for any type of memory. TCAM benefits greatly because all locations in the TCAM are looked up using the packet in a given cycle to find the best match for the packet. For typical SRAM, in contrast, the memory looks up one location by address. If that one location has a parity error, then the error is declared and the packet is dropped or some other action is taken. With TCAM, all locations are looked up and all locations would have to be checked for a parity error. TCAMs tend to be large, e.g., 128 to 512 deep×80, 96, or wider, and sequentially performing with software (e.g., via DMA read instructions) a complete line by line scan of every data line in every TCAM can be a very time consuming (consuming even up to seconds of time), power consuming, and CPU intensive operation. The highly parallelized hardware parity checking described above reduces a complete parity check across all TCAMs to hundreds of microseconds, or less, without generating any appreciable CPU or software load.

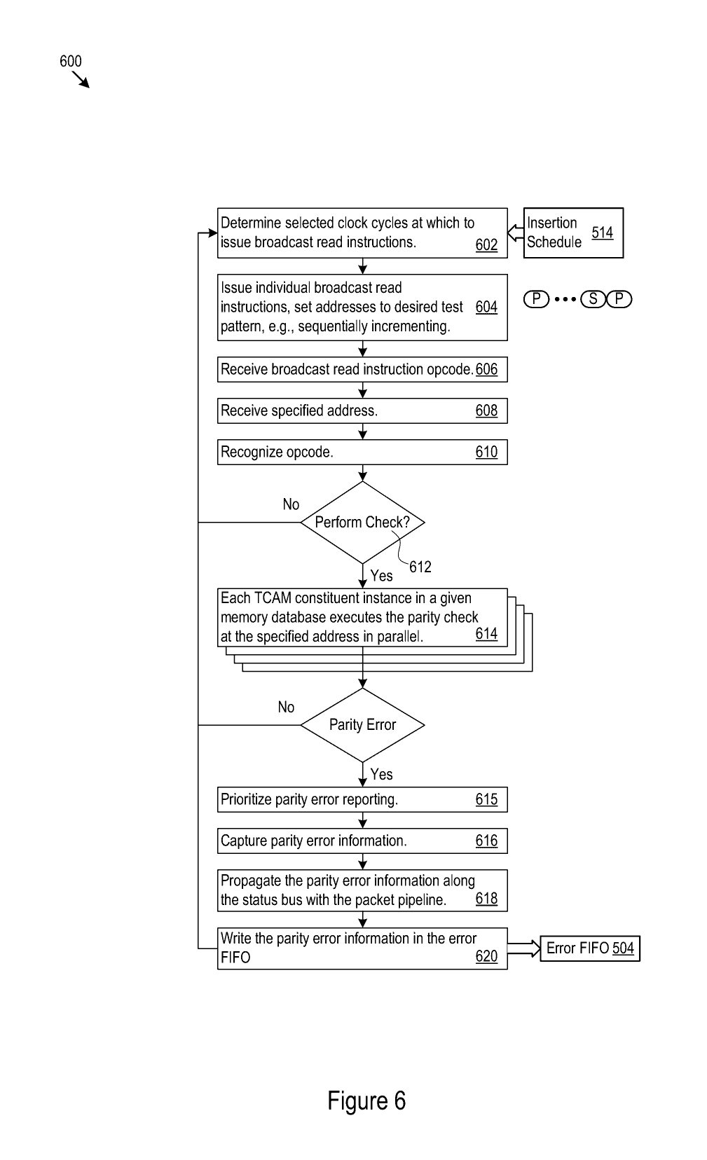

FIG. 6 shows corresponding logic 600 that a system may implement to perform parallel processing of parity checks. The logic 600 determines selected clock cycles at which to issue the broadcast read instructions (602). The logic 600 may determine the insertion events with reference to the insertion schedule 514, or to meet a pre-configured rate. As noted above, the insertion schedule 514 may be configured to provide an amount of guaranteed bandwidth into the packet pipeline 206 for, e.g., control, configuration, metering, or for other reasons.

The logic 600 also includes issuing individual broadcast read instructions (604). The pipeline control circuitry 204 may specify sequentially incrementing addresses. However, the address may follow any desired test pattern or address sequence.

The circuitry at each pipeline stage may recognize and respond to the broadcast read instructions. In particular, the memory databases may recognize the broadcast read instruction 512 and perform a parity test responsive to the broadcast read instruction 512. In doing so, each memory database may receive the broadcast read instruction opcode 212 (606) and the specified address 214 (608), and recognize the instruction opcode 212 as a broadcast read instruction (610).

Memory databases may ignore broadcast read instructions made to addresses outside the range of that particular memory database (612), or for other reasons. The memory databases may recognize the broadcast read instruction and perform a parity test responsive to the broadcast read instruction. In doing so, each TCAM constituent instance in a given memory database may execute the parity check at the specified address (614).

The logic 600 prioritizes among multiple parity error outputs (615). The logic 600 also captures parity error information to the status bus (616), propagates the parity error information along the pipeline (618), and writes the parity error information in the error FIFO (620). As noted above, the parity error information may include an identifier (e.g. an address) of the memory database in which the parity error occurred, the address within the memory database of the parity error, and additional status information, such as the number of parity errors, and (when there are multiple parity bits per data line) which parity bits indicate parity errors.

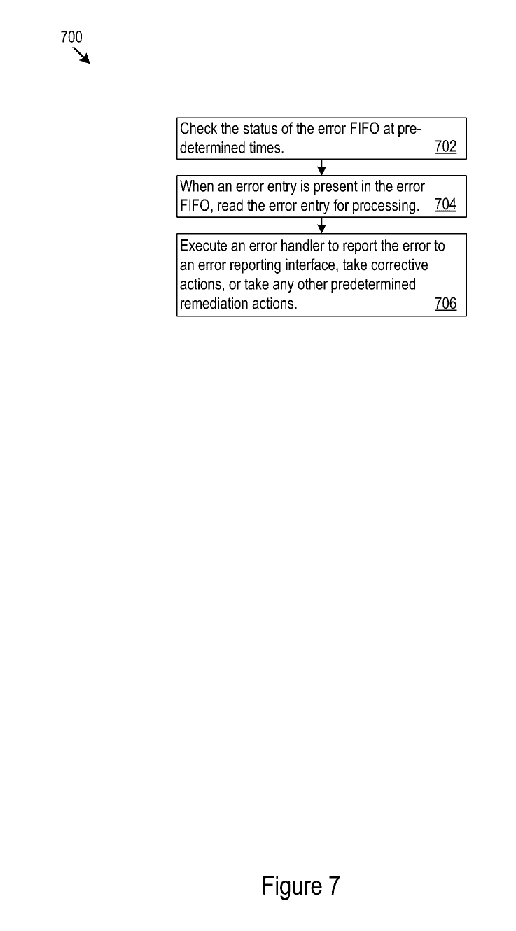

FIG. 7 shows logic 700 for parity error handling. A host CPU 506 (or any other processing circuitry) may check the status of the error FIFO 504 at pre-determined times (702). When an error entry is present in the error FIFO 504, the host CPU 506 may read the error entry for processing (704). The host CPU 506 may execute an error handler 510 to report the error locally or remotely to an error reporting interface, take corrective actions, or take any other predetermined remediation actions (706).

The methods, devices, processing, and logic described above may be implemented in many different ways and in many different combinations of hardware and software. For example, all or parts of the implementations may be circuitry that includes an instruction processor, such as a Central Processing Unit (CPU), microcontroller, or a microprocessor; an Application Specific Integrated Circuit (ASIC), Programmable Logic Device (PLD), or Field Programmable Gate Array (FPGA); or circuitry that includes discrete logic or other circuit components, including analog circuit components, digital circuit components or both; or any combination thereof. The circuitry may include discrete interconnected hardware components and/or may be combined on a single integrated circuit die, distributed among multiple integrated circuit dies, or implemented in a Multiple Chip Module (MCM) of multiple integrated circuit dies in a common package, as examples.

The circuitry may further include or access instructions for execution by the circuitry. The instructions may be stored in a tangible storage medium that is other than a transitory signal, such as a flash memory, a Random Access Memory (RAM), a Read Only Memory (ROM), an Erasable Programmable Read Only Memory (EPROM); or on a magnetic or optical disc, such as a Compact Disc Read Only Memory (CDROM), Hard Disk Drive (HDD), or other magnetic or optical disk; or in or on another machine-readable medium. A product, such as a computer program product, may include a storage medium and instructions stored in or on the medium, and the instructions when executed by the circuitry in a device may cause the device to implement any of the processing described above or illustrated in the drawings.

The implementations may be distributed as circuitry among multiple system components, such as among multiple processors and memories, optionally including multiple distributed processing systems. Parameters, databases, and other data structures may be separately stored and managed, may be incorporated into a single memory or database, may be logically and physically organized in many different ways, and may be implemented in many different ways, including as data structures such as linked lists, hash tables, arrays, records, objects, or implicit storage mechanisms. Programs may be parts (e.g., subroutines) of a single program, separate programs, distributed across several memories and processors, or implemented in many different ways, such as in a library, such as a shared library (e.g., a Dynamic Link Library (DLL)). The DLL, for example, may store instructions that perform any of the processing described above or illustrated in the drawings, when executed by the circuitry.

Various implementations have been specifically described. However, many other implementations are also possible.

What is claimed is:

1. A system comprising:
a packet processing pipeline comprising:
a first pipeline stage; and
a second pipeline stage subsequent to the first pipeline stage;
a controller configured to:
issue a broadcast read instruction into the packet processing pipeline;
a first memory at the first pipeline stage, the first memory configured to:
recognize the broadcast read instruction; and
perform a parity test of the first memory responsive to the broadcast read instruction;
a second memory at the second pipeline stage, the second memory configured to:
recognize the broadcast read instruction; and
perform a parity test of the second memory responsive to the broadcast read instruction.

2. The system of claim 1, where:
the broadcast read instruction comprises:
an opcode identifying the broadcast read instruction for execution by both the first memory and the second memory; and
a memory address within both the first memory and the second memory at which to perform the parity tests.

3. The system of claim 1, where the first memory comprises:
parity check logic operable to determine whether a parity error exists in the first memory.

4. The system of claim 1, where the first memory comprises:
parity compute logic operable to determine parity to store in the first memory.

5. The system of claim 1, where the first memory comprises:
a data bit array; and
a parity bit array for the data bit array.

6. The system of claim 5, where:
the parity bit array comprises an interleaved parity bit array.

7. The system of claim 6, where:
the interleaved parity bit array comprises an at least two bit interleaved parity bit array.

8. The system of claim 1, where:
the first memory comprises:
a first memory module; and
a second memory module; and where:
the first memory is configured to execute the parity test of the first memory on both the first memory module and the second memory module in parallel.

9. The system of claim 8, where:
the first and second memory module each comprise parity check logic operable to determine whether a parity error exists in their respective module.

10. The system of claim 8, where:
the first and second memory module each comprise parity compute logic operable to determine parity to store in their respective module.

11. The system of claim 8, where the first memory module and the second memory module comprise individual instances of a pre-defined macro block.

12. The system of claim 8, where:
the first memory module comprises a first parity output;
the second memory module comprises a second parity output; and
further comprising error arbitration logic operable to prioritize between the first parity output and the second parity output.

13. A method comprising:
receiving a scan instruction at a first ternary content addressable memory (TCAM) at a first pipeline stage; and
responsive to the scan instruction, performing a first parity check in parallel over multiple TCAM constituent modules comprising the first TCAM at the first pipeline stage.

14. The method of claim 13, further comprising:
receiving the scan instruction at a second ternary content addressable memory (TCAM) at a second pipeline stage; and
responsive to the scan instruction, performing a second parity check in parallel over multiple TCAM constituent modules comprising the second TCAM at the second pipeline stage.

15. The method of claim 13, where receiving comprises:
receiving an opcode and an address; and further comprising:
recognizing the opcode as a broadcast read instruction; and
performing the first parity check in each TCAM constituent module at the address.

16. The method of claim 13, where the first pipeline stage is part of a packet processing pipeline, and further comprising:
determining a selected cycle at which to issue the scan instruction, the selected cycle occurring during a pre-scheduled overhead pipeline access time period; and
issuing the scan instruction into the packet processing pipeline at the selected cycle.

17. The method of claim 13, further comprising:
arbitrating error reporting between the multiple TCAM constituent modules when there is more than one parity error in the first TCAM.

18. The method of claim 13, where the scan instruction is part of a set of scan instructions, and further comprising:
issuing the set of scan instructions with addresses in the set configured to test each memory line in the multiple TCAM constituent modules.

19. A system comprising:
a packet pipeline comprising:
a first pipeline stage; and
a second pipeline stage subsequent to the first pipeline stage;
a first ternary content addressable memory (TCAM) at the first pipeline stage, the first TCAM comprising:
a first instance of a pre-defined TCAM unit layout; and
a second instance of the pre-defined TCAM unit layout;
a second ternary content addressable memory (TCAM) at the second pipeline stage, the second TCAM comprising:
a third instance of the pre-defined TCAM unit layout; and
a controller in communication with the packet pipeline, the controller configured to:
sequentially issue a set of individual broadcast test instructions into the packet pipeline to test parity in parallel across the first TCAM and the second TCAM, the individual broadcast test instructions comprising:
an instruction opcode identifying the individual broadcast test instructions as parity test instructions for both the first TCAM and the second TCAM to execute; and
an address field for specifying memory addresses at which to test parity in both the first TCAM and the second TCAM;
the first TCAM configured to:
receive the set of individual broadcast test instructions; and
perform first individual parity tests of the first instance at the memory addresses responsive to the set of individual broadcast test instructions;
in parallel with the first parity test, perform second individual parity tests of the second instance at the memory addresses responsive to the set of individual broadcast test instructions; and
the second TCAM configured to:
receive the set of broadcast test instructions; and
perform third individual parity tests of the third instance at the memory address responsive to the set of broadcast test instructions.

20. The system of claim 19, where the controller is further configured to:
determine time periods during which pre-scheduled pipeline overhead access will occur for the packet pipeline;
from among the time periods, determine selected cycles at which to issue the set of individual broadcast test instructions; and
sequentially issue the individual broadcast test instructions into the packet pipeline at the selected cycles.
